(19) United States
(12) Patent Application Publication
(10) Pub. No.: US 2026/0370157 A1
(43) Pub. Date: Nov. 19, 2026

(54) POWER CONVERTER

(71) Applicants: HITACHI ASTEMO, LTD., IBARAKI (JP); ASTEMO, LTD., Tokyo (JP)

(72) Inventors: Takahiro ARAKI, Tokyo (JP); Kyota ASAI, Tokyo (JP); Hironori NAGASAKI, Tokyo (JP); Shigehisa AOYAGI, Hitachinaka-shi (JP); Kiyotaka KANNO, Hitachinaka-shi (JP)

(21) Appl. No.: 19/515,521

(22) PCT Filed: Oct. 18, 2024
(86) PCT No.: PCT/JP2024/037201

§ 371 Date: Mar. 2, 2026

(30) Foreign Application Priority Data
Oct. 20, 2023 (JP) 2023-181481

(51) Int. Cl. H02M 7/537; H02M 7/00; H02M 7/493; H10W 70/40; H10W 70/68

(52) U.S. Cl. CPC H02M 7/537; H02M 7/003; H02M 7/493; H10W 70/429; H10W 70/682

(57) ABSTRACT

A power converter includes: a semiconductor package in which a semiconductor element is incorporated, and that has a terminal for connecting, the terminal protruding outward; and a wiring substrate on which the semiconductor package is mounted, in which the terminal includes: a bent portion that is bent on a plane that is in parallel with the wiring substrate; and a terminal connecting portion that is provided further on a tip-end side with respect to the bent portion, the wiring substrate includes: a first wiring portion that is provided on a substrate surface and to which the terminal is bonded; and another second wiring portion, and the first wiring portion extends from a connecting section where the terminal is connected, toward the semiconductor package, in a manner facing and extending along the terminal, and has an end connected to the second wiring portion, the end being on an extending side.

### TECHNICAL FIELD

The present invention relates to a power converter.

### BACKGROUND ART

Conventionally, in a power converter such as an inverter, a semiconductor package implementing the inverter circuit is mounted on a wiring substrate. In such a power converter, to improve the reliability (e.g. cycle tolerance), there is a demand for alleviating the stress in a solder-bonded portion where terminals of the semiconductor package are bonded to the wiring substrate.

For example, PTL 1 discloses a terminal structure in which a bent portion is provided to the terminal to alleviate the stress in the solder-bonded portion. By providing the bent portion, the stress in the solder-bonded portion can be alleviated.

### CITATION LIST

### Patent Literature

PTL 1: JP 4476465 B

### SUMMARY OF INVENTION

### Technical Problem

However, when the terminal has a bent structure, there arises a problem that the terminal becomes elongated, and the inductance of the terminal portion increases accordingly. In a main terminal where high current is passed, it is necessary to avoid such an increase of inductance, so that it has been difficult to apply a bent structure to the main terminal.

### Solution to Problem

A power converter according to an aspect of the present invention includes: a semiconductor package in which a semiconductor element is incorporated, and that has a terminal for connecting, the terminal protruding outward; and a wiring substrate on which the semiconductor package is mounted, in which the terminal includes: a bent portion that is bent on a plane that is in parallel with the wiring substrate; and a terminal connecting portion that is provided further on a tip-end side with respect to the bent portion, the wiring substrate includes: a first wiring portion that is provided on a substrate surface and to which the terminal is bonded; and another second wiring portion, and the first wiring portion extends from a connecting section where the terminal is connected, toward the semiconductor package, in a manner facing and extending along the terminal, and has an end connected to the second wiring portion, the end being on an extending side.

### Advantageous Effects of Invention

According to the present invention, it is possible to achieve the alleviation of stress and a reduction of the inductance at the same time.

### BRIEF DESCRIPTION OF DRAWINGS

FIG. 1 is a diagram illustrating a schematic configuration of a power converter.

FIG. 2 is a diagram illustrating a configuration of an inverter circuit.

FIG. 3 is a diagram illustrating a semiconductor package mounted on a wiring substrate.

FIG. 4 is a cross-sectional view taken along line A-A in FIG. 3.

FIG. 5 is a diagram illustrating an example of an arrangement of semiconductor packages corresponding to the upper and the lower arms, on a wiring substrate.

FIG. 6 is a diagram illustrating a modification of the configuration illustrated in FIG. 4.

FIG. 7 is a diagram illustrating a configuration of an inverter circuit according to a second embodiment.

FIG. 8 is a diagram schematically illustrating an arrangement of components of a U-phase inverter circuit on a wiring substrate.

FIG. 9 is a cross-sectional view taken along line B-B in FIG. 8.

FIG. 10 is a diagram illustrating a comparative example.

### DESCRIPTION OF EMBODIMENTS

Some modes for carrying out the present invention will now be explained with reference to drawings. The description hereunder and the drawings are illustrative examples for explaining the present invention, and omissions and simplification are made as appropriate, for the sake of clarity of description. In the following description, redundant description may be omitted by assigning the same reference numerals to the same or similar elements and processes. Note that content described below is merely an example of embodiments of the present invention, and the present invention is not limited to the embodiments described below, and may be carried out in any other various modes.

### First Embodiment

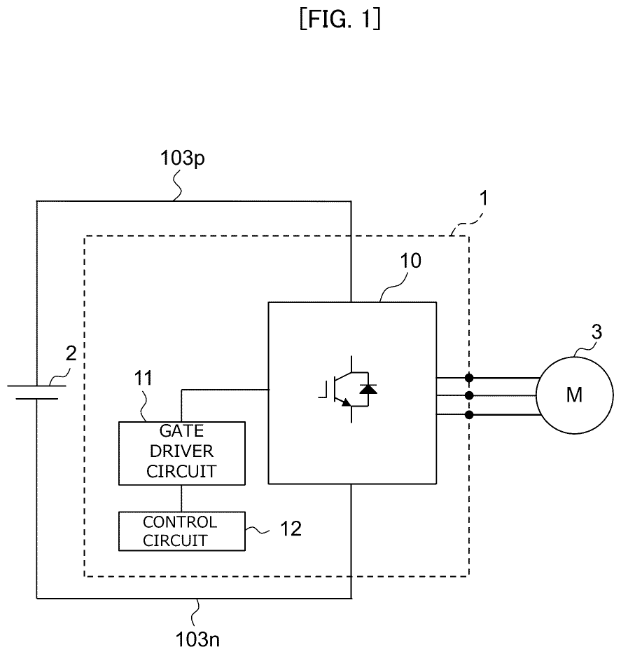

FIG. 1 is a diagram illustrating a schematic configuration of a power converter 1. The power converter 1 converts DC power supplied from a DC voltage source 2 such as a battery into AC power, and drives a motor 3. Further, during a braking operation of the motor 3, the power converter 1 is controlled regeneratively so as to convert the AC power into the DC power. The power converter 1 includes an inverter circuit 10, a gate driver circuit 11, and a control circuit 12. The inverter circuit 10 includes a plurality of semiconductor elements that perform switching operations. The inverter circuit 10 is connected to the DC voltage source 2 via a positive electrode wiring 103p and a negative electrode wiring 103n. The control circuit 12 is implemented as a microcomputer, a CPU, or the like.

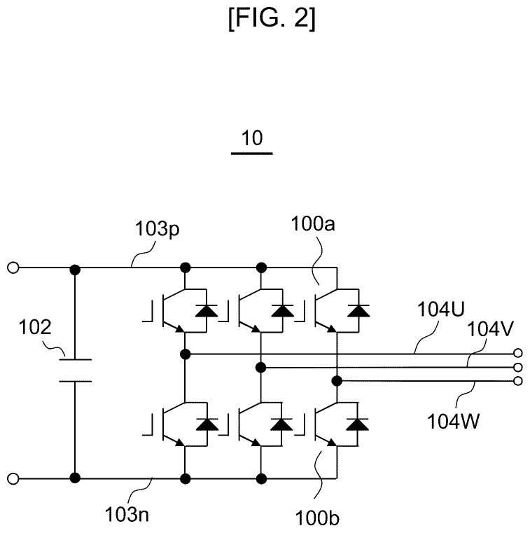

FIG. 2 is a diagram illustrating a configuration of the inverter circuit 10. The inverter circuit 10 includes a pair of semiconductor elements 100a, 100b forming an upper and lower arms, for each of the U phase, the V phase, and the W phase. As the semiconductor element 100a, 100b, an insulated gate bipolar transistor (IGBT), a metal oxide semiconductor field effect transistor (MOSFET), or the like is used. The semiconductor element 100a, 100b is provided with three terminals including a high-voltage side terminal for a main circuit (the collector terminal of an IGBT, or the drain terminal of a MOSFET, for example), a low-voltage side terminal for the main circuit (the emitter terminal of an IGBT, the source terminal of an MOSFET, for example), and a signal terminal (such as a gate terminal).

The semiconductor elements 100a, 100b implementing the U phase, the V phase, and the W phase upper and lower arms are connected in parallel between the positive electrode wiring 103p and the negative electrode wiring 103n that are connected to the DC voltage source 2. A capacitor 102 provided between the positive electrode wiring 103p and the negative electrode wiring 103n is a smoothing capacitor for smoothing the current generated by on/off of the semiconductor elements 100a, 100b.

The main-circuit low-voltage side terminal of the upper-arm semiconductor element 100a and the main-circuit high-voltage side terminal of the lower-arm semiconductor element 100b corresponding to the U phase are connected to a U-phase output wiring 104U. The main-circuit low-voltage side terminal of the upper-arm semiconductor element 100a and the main-circuit high-voltage side terminal of the lower-arm semiconductor element 100b corresponding to the V phase are connected to a V-phase output wiring 104V. The main-circuit low-voltage side terminal of the upper-arm semiconductor element 100a and the main-circuit high-voltage side terminal of the lower-arm semiconductor element 100b corresponding to the W phase are connected to a W-phase output wiring 104W. Each of the phase output wirings 104U, 104V, and 104W is connected to the motor 3. The signal terminal of each of the semiconductor elements 100a, 100b is connected to the gate driver circuit 11 illustrated in FIG. 1, and the semiconductor elements 100a, 100b are switched on or off on the basis of a signal input from the control circuit 12.

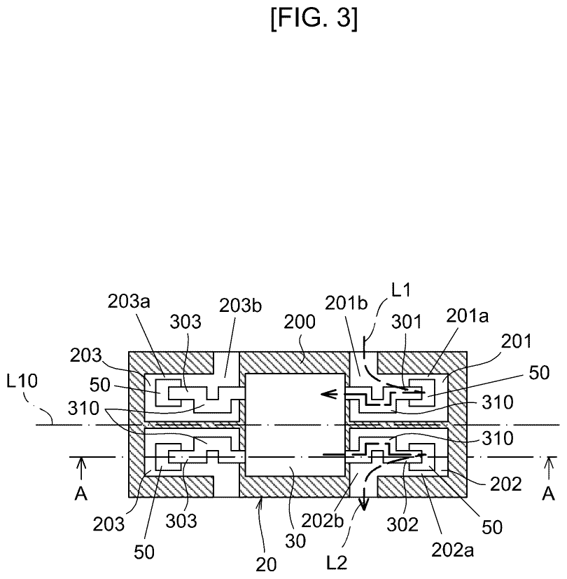

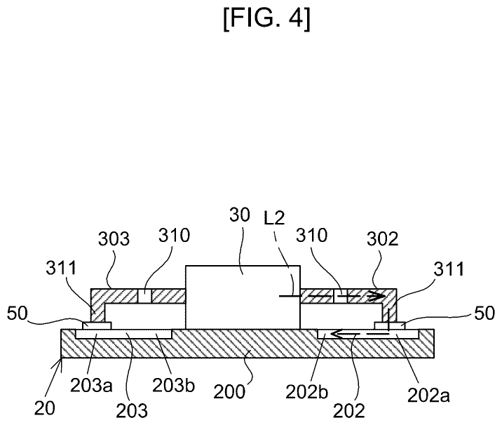

FIG. 3 is a diagram illustrating a semiconductor package 30 mounted on the wiring substrate 20. FIG. 4 is a diagram schematically illustrating the cross section taken along line A-A in FIG. 3. Each of the semiconductor elements 100a, 100b is incorporated in the semiconductor package 30 made of an insulating material. In the semiconductor package 30 illustrated in FIG. 3, the semiconductor element 100a or the semiconductor element 100b described above is incorporated. A plurality of terminals 301, 302, 303 protrude from the semiconductor package 30, in parallel with the substrate surface of the wiring substrate 20.

The terminal 301 is the main-circuit high-voltage side terminal described above. The terminal 302 is the main-circuit low-voltage side terminal described above. The terminal 303 is the signal terminal described above. Each of the terminals 301, 302, 303 has a bent portion 310. Each of the terminals 301 to 303 also has a terminal connecting portion 311 at the tip thereof, as illustrated in FIG. 4. The terminal connecting portion 311 is bonded to corresponding one of wiring portions 201 to 203 of the wiring substrate 20, using a bonding material 50 such as solder.

The wiring portion 201 provided on the substrate surface of the wiring substrate 20 extends in the direction in which the terminal 301 extends, and is disposed facing the terminal 301. The terminal connecting portion 311 of the terminal 301 is solder-bonded to one end of the wiring portion 201, which is on the right side in the drawing. The other end 201b of the wiring portion 201 is connected to another wiring portion, not illustrated. For example, when the semiconductor element 100a illustrated in FIG. 2 is incorporated in the semiconductor package 30, the wiring portion 201 is connected to the positive electrode wiring 103p. When the U-phase lower-arm semiconductor element 100a is incorporated in the semiconductor package 30, the wiring portion 201 is connected to the U-phase output wiring 104U. Similarly, each of the wiring portions 202, 203 extends in the direction in which the terminal 302, 303 extends, and is disposed facing the terminal 302, 303. The terminal connecting portion 311 of the terminal 302, 303 is solder-bonded to one end of the wiring portion 202, 203.

As illustrated in FIGS. 3 and 4, in this embodiment, the terminal 301 to 303 is provided with the bent portion 310. The stress exerted on the terminal connecting portion 311 is therefore alleviated through slight deformation of the bent portion 310, so that it is possible to alleviate the stress in the solder-bonded portion.

The broken-line arrows L1 in FIGS. 3 and 4 schematically illustrate the flow of current flowing from the wiring portion 201, through the terminal 302, into the semiconductor package 30. Similarly, the broken-line arrow L2 illustrates the flow of current flowing from the semiconductor package 30, through the terminal 302, into the wiring portion 202. As indicated by the broken-line arrows L1 and L2, the currents flowing through the terminals 301, 302 and the currents flowing through the wiring portions 201, 202 facing each other are in opposite directions with respect to each other. As a result, the magnetic fluxes generated by these currents cancel out each other, so that the inductance of the terminal portions can be reduced. In other words, in this embodiment, it is possible to achieve stress alleviation in the terminal connecting portion 311, as well as inductance reduction. The terminal 303, which is a signal terminal, has a relationship with the wiring portion 203, similar to those of the terminals 301, 302.

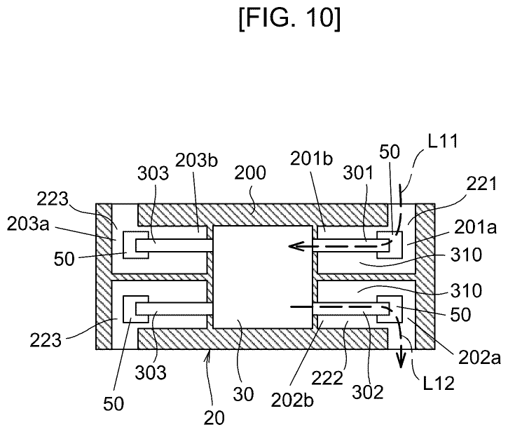

FIG. 10 is a diagram illustrating a comparative example. In the configuration of wiring portions 221 to 223 illustrated in FIG. 10, the side of each of one ends 201a, 202a, 203a, which are solder-bonded with the terminal connecting portions 311 of the terminals 301 to 303, is connected to another wiring portion. Therefore, the current flowing into the semiconductor package 30, via the terminal 301, is as indicated by the broken-line e arrow L11. By contrast, the current flowing out of the semiconductor package 30 via the terminal 302 flows as indicated by the broken-line arrow L12. Therefore, unlike the example illustrated in FIGS. 3 and 4, the currents flowing through the wiring portions 221, 222 do not flow in the opposite directions with respect to the direction of the currents flowing through the terminals 301, 302, and the wiring portions 221, 222 do not face the terminals 301, 302, either. As a result, in the comparative example, the inductance-reducing effect of the currents flowing through the wiring portions cannot be achieved. Therefore, even with the bent portion 310 illustrated in FIGS. 3 and 4 provided to the terminal 301 to 303, although the stress in the solder-bonded portion can be alleviated, there is a disadvantage that inductance is increased, oppositely.

As illustrated in FIG. 3, the bent portions 310 of the terminals 301, 302 protruding from the same side surface of the semiconductor package 30 are bent in directions approaching each other. In other words, the bent portion 310 of the terminal 301 is bent toward the terminal 302 (downward in the drawing), and the bent portion 310 of the terminal 302 is bent toward the terminal 301 (upward in the drawing). By bending the adjacent bent portions 310 in directions approaching each other, as described above, it is possible to further reduce the inductances. Furthermore, the inductance-reducing effect can be further enhanced by matching positions of the bent portions 310 facing each other, in the left-right direction in the drawing. As illustrated in FIG. 3, it is preferable for the pair of terminals 303 protruding from the semiconductor package 30 toward the left in the drawing to have the same configurations of the bent portions 310 as those of the terminals 301, 302.

Furthermore, comparing the terminals 301, 303 on the upper side of the drawing with the terminals 302, 303 on the lower side of the drawing, the shapes and arrangement of the terminals are line-symmetric to each other with respect to a line L10 passing through the center of the semiconductor package 30 in the up-down direction. As described above, by making the shapes and arrangement of the terminals line-symmetric, it is possible to suppress displacement of the semiconductor package 30 in the planar directions when the terminals 301 to 303 extend or contract due to a change in temperature. For example, in a case where a cooling element is provided to the top surface of the semiconductor package 30, with an insulating member interposed therebetween, the stress exerted on the insulating member is alleviated, and reliability related to cooling can be improved.

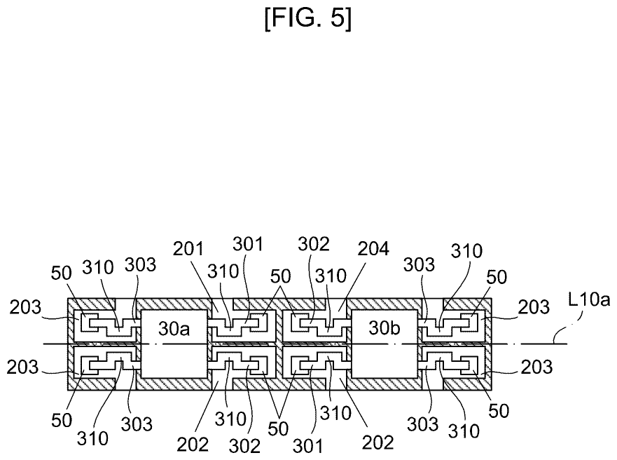

FIG. 5 is a diagram illustrating an example of the arrangement of the semiconductor packages 30a, 30b corresponding to the upper and lower arms, on the wiring substrate 20. In the example illustrated in FIG. 5, the U-phase upper-arm semiconductor element 100a illustrated in FIG. 2 is incorporated in the semiconductor package 30a, and the U-phase lower-arm semiconductor element 100b is incorporated in the semiconductor package 30b. The terminals 301 to 303 of the semiconductor package 30a and the wiring portions 201 to 203 connected to the terminals 301 to 303 have the same configurations as those illustrated in FIGS. 3 and 4.

In the semiconductor package 30b in which the lower-arm semiconductor element 100b is incorporated, the terminals 301, 302 that are the main-circuit terminals are provided on the left side of the package in the drawing, and the terminals 303 that are the signal terminals are provided on the right side of the package in the drawing. Further, the terminal 301 that is the main-circuit high-voltage side terminal is provided on the lower side in the drawing, and the terminal 302 that is the main-circuit low-voltage side terminal is provided on the upper side in the drawing. The terminal 301 of the semiconductor package 30b is bonded to the wiring portion 202, and the terminal 302 is bonded to the wiring portion 204. The wiring portion 202 is connected to the U-phase output wiring 104U illustrated in FIG. 2. By contrast, the wiring portion 204 is connected to the negative electrode wiring 103n.

Also in the example illustrated in FIG. 5, by providing the bent portions 310 to the terminals 301 to 302, the stress in the terminal connecting portions 311 can be alleviated. Furthermore, because the bent portions 310 of the terminals that are adjacent to each other in the up-down direction in the drawing are bent in directions approaching each other, the inductance-reducing effect can be improved, similarly to the example illustrated in FIGS. 3 and 4. Also in the case illustrated in FIG. 5, because the shapes and the arrangement of the terminals of the semiconductor packages 30a, 30b disposed side by side form a line-symmetric structure with respect to a line L10a, it is possible to suppress displacement of the semiconductor packages 30a, 30b in planar directions when the terminals extend or contract due to a change in temperature.

### Modification

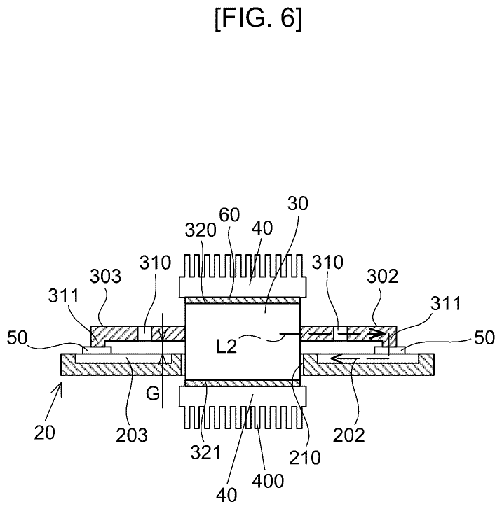

FIG. 6 is a diagram illustrating a modification of the configuration illustrated in FIG. 4. In the configuration illustrated in FIG. 4, the semiconductor package 30 is provided on the front surface of the wiring substrate 20. By contrast, in the modification illustrated in FIG. 6, a through hole 210 is provided in the wiring substrate 20, and the semiconductor package 30 is inserted into the through hole 210 and disposed in such a manner that the rear surface thereof protrudes from the rear surface of the wiring substrate 20. Therefore, a gap dimension G between the terminal 301 to 303 and the wiring portion 201 to 203 can be set smaller than that in the structure illustrated in FIG. 4, and the inductance-reducing effect can be further improved.

As described above, in the structure in which the semiconductor package 30 is inserted into the through hole 210, the gap dimension G can be reduced, regardless of the thickness of the semiconductor package 30. In a case where heat-dissipating surfaces 320, 321 are provided on both of the front and rear surfaces of semiconductor package 30, with the use of configuration in which the semiconductor package 30 is inserted into the through hole 210, it becomes possible to place cooling elements 40 on the respective heat-dissipating surfaces 320, 321. That is, the semiconductor package 30 can be cooled from both of the top and the bottom surfaces, SO that cooling performance can be improved. Although a heat-dissipating element including a large number of pin fins 400 is used as the cooling element 40 illustrated in FIG. 6, it is also possible to use a cooling element that uses a refrigerant. Between the cooling element 40 and the semiconductor package 30, an electrically insulating heat conducting member 60 is provided.

### Second Embodiment

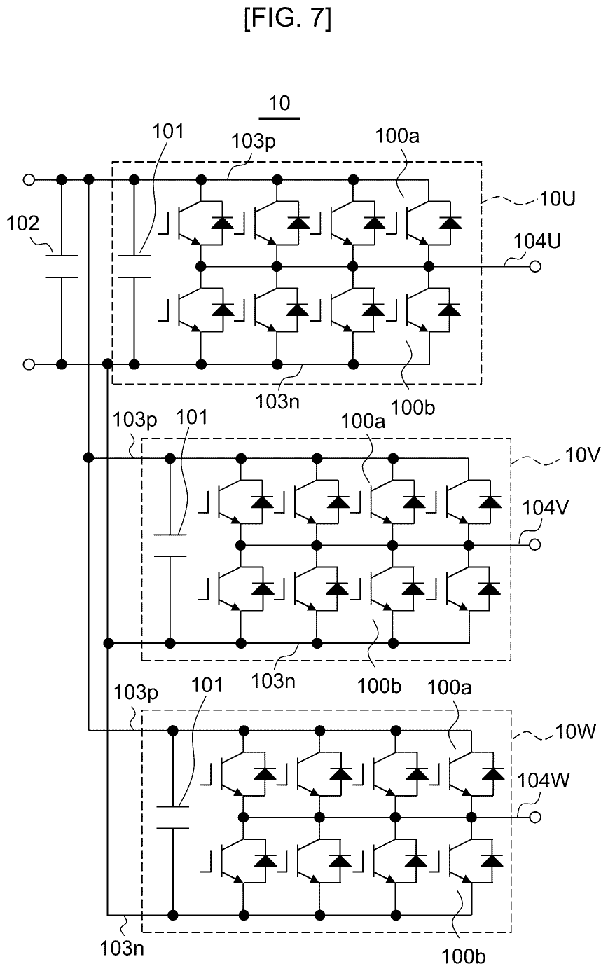

In the first embodiment described above, the upper and lower arms corresponding to each of the phases are configured by the pair of semiconductor elements 100a, 100b, as illustrated in FIG. 2. By contrast, in a second embodiment, as illustrated in FIG. 7, an example in which the upper and lower arms corresponding to each of the phases are configured by a plurality of pairs of semiconductor elements 100a, 100b will be described. FIG. 7 is a diagram illustrating a configuration of the inverter circuit 10 illustrated in FIG. 1. The inverter circuit 10 includes a U-phase inverter circuit 10U, a V-phase inverter circuit 10V, and a W-phase inverter circuit 10W.

Each of the U-phase inverter circuit 10U, the V-phase inverter circuit 10V, and the W-phase inverter circuit 10W includes a plurality of sets of upper-and lower-arm semiconductor elements. In the example illustrated in FIG. 7, the output current of the power converter 1 is increased by connecting four sets of serially connected upper-and lower-arm semiconductor elements 100a, 100b in parallel. Each of the U-phase, V-phase, and W-phase inverter circuits 10U, 10V, and 10W is configured by pairing the capacitor 101 with the serially £ connected upper-and lower-arm semiconductor elements 100a, 100b. The positive electrode terminal of the capacitor 101 is connected to the main-circuit high-voltage side terminals of the upper-arm semiconductor elements 100a, by the positive electrode wiring 103p. The negative electrode terminal of the capacitor 101 is connected to the main-circuit low-voltage side terminals of the lower-arm semiconductor elements 100b, by the negative electrode wiring 103n.

The main-circuit low-voltage side terminals of the upper-arm semiconductor elements 100a of the U-phase inverter circuit 10U are connected to the main-circuit high-voltage side terminals of the lower-arm semiconductor elements 100b, by the U-phase output wiring 104U. The main-circuit low-voltage side terminals of the upper-arm semiconductor elements 100a of the V-phase inverter circuit 10V are connected to the main-circuit high-voltage side terminals of the lower-arm semiconductor elements 100b, by the V-phase output wiring 104V. The main-circuit low-voltage side terminals of the upper-arm semiconductor elements 100a of the W-phase inverter circuit 10W are connected to the main-circuit high-voltage side terminals of the lower-arm semiconductor elements 100b, by the w-phase output wiring 104W. Each of the phase output wirings 104U, 104V, and 104W is connected to the motor 3 (see FIG. 1).

The U-phase, V-phase, and W-phase inverter circuits 10U, 10V, and 10W are connected in parallel with the capacitor 102. A small ceramic capacitor is used as the capacitor 101, and a film capacitor having a large electrostatic capacitance is used as the capacitor 102. By disposing the capacitors 101, 102 near the semiconductor elements 100a, 100b, the wiring inductance of the positive electrode wiring 103p and the negative electrode wiring 103n can be reduced.

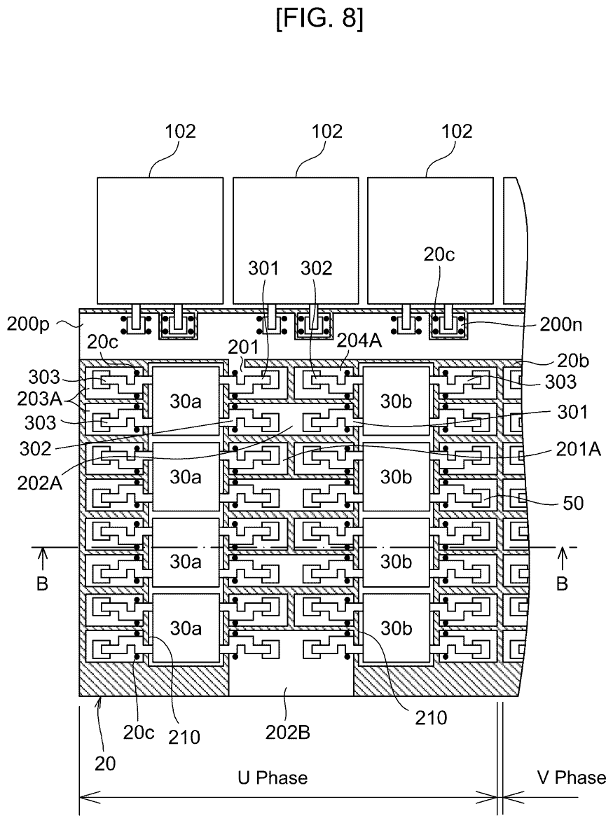

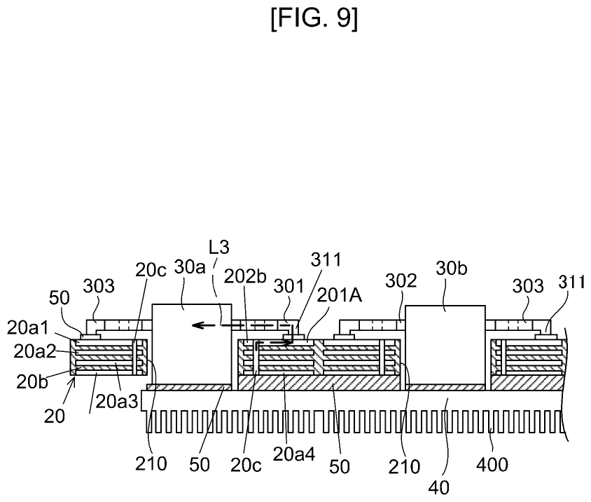

FIG. 8 is a diagram illustrating a part of the inverter circuit 10, and is a diagram schematically illustrating an arrangement of components of the U-phase inverter circuit 10U on the wiring substrate 20. FIG. 9 is a diagram schematically illustrating the cross section taken along line B-B in FIG. 8. The arrangement of the semiconductor packages 30a, 30b in FIG. 8 corresponds to an arrangement in which four pairs of semiconductor packages 30a, 30b illustrated in FIG. 5 are disposed along the up-down direction in the drawing. Although, in FIG. 5, the wiring portion 202 to which the terminal 302 of the semiconductor package 30a is connected is separated from the wiring portion 202 to which the terminal 301 of the semiconductor package 30b is connected, common wiring portions 202A, 202B are used in FIG. 8 instead.

Note that only the area where the U-phase components are disposed is illustrated in FIG. 8, and the areas where the V-phase components and the W-phase components are disposed are omitted. The V-phase components and the W-phase components are disposed in the area on the right side, not illustrated, in the wiring substrate 20 in FIG. 8.

A multilayer substrate is used as the wiring substrate 20, and wiring layers (conductor layers) 20al to 20a4 and insulating layers 20b are laminated alternately, as illustrated in FIG. 9. Wiring portions 200p, 200n, 201, 201A, 202A, 202B, 203A, and 204A illustrated in FIG. 8 are formed on a wiring layer 20al on the front surface side of the wiring substrate 20.

The wiring portion 200p is a wiring portion corresponding to the positive electrode wiring 103p in FIG. 7. The wiring portion 200p and the wiring portions 201, 201A are connected to each other via at least one of an interlayer connecting portion 20c formed in the substrate thickness direction and other wiring layers 20a2 to 20a4. The wiring portion 200n is a wiring portion corresponding to the negative electrode wiring 103n in FIG. 7. The wiring portion 200n and the wiring portion 204A are connected to each other via at least one of the interlayer connecting portion 20c and the other wiring layers 20a2 to 20a4.

The wiring portions 202A, 202B are wiring portions corresponding to the wiring portion 202 in FIG. 5. The wiring portions 202A, 202B are connected to each other via at least one of the interlayer connecting portion 20c and the other wiring layers 20a2 to 20a4. The wiring portion 202B is connected to the U-phase output wiring 104U (see FIG. 7) that is another wiring portion.

Similarly to the example illustrated in FIG. 6, through holes 210 are formed in the wiring substrate 20, and each of the semiconductor packages 30a, 30b is mounted on the wiring substrate 20 in a manner inserted into the corresponding through hole 210. As illustrated in FIG. 9, a heat-dissipating element provided with a large number of pin fins 400 is disposed as the cooling element 40 on the rear surface of the wiring substrate 20 (on the lower side in the drawing). The cooling element 40 is thermally connected to the semiconductor packages 30a, 30b and the rear surface of the wiring substrate 20 via an electrically insulating heat conducting member 60. As the cooling element 40, a cooling element using a refrigerant may also be used, instead of the heat-dissipating element described above.

When the semiconductor elements 100a, 100b in the semiconductor packages 30a, 30b are switched on and off, the temperature of the semiconductor packages 30a, 30b and the terminal 301, 302 increases. By providing the cooling element 40 as illustrated in FIG. 9, the heat of the semiconductor packages 30a, 30b and the terminal 301, 302 is dissipated effectively, so that it is possible to suppress a temperature rise of the semiconductor packages 30a, 30b, the terminal 301, 302, and the wiring substrate 20. As a result, deformation of members due to a temperature rise is suppressed, and stress in the solder-bonded portion can be alleviated.

The cooling element 40 may also be disposed on each of the front surfaces of the semiconductor packages 30a, 30b, the configuration of which is not illustrated, to cool the semiconductor packages 30a, 30b from both of the upper and lower surfaces. In this manner, cooling performance can be further improved.

As described above, in the second embodiment, too, the bent portion 310 is provided to the terminal 301 to 303, and each of the wiring portions disposed in a manner facing the terminal 301 to 303 extends along a terminal-protruding direction. To one end of each of the wiring portions, the terminal connecting portion 311 of the corresponding terminal 301 to 303 is solder-bonded, and the interlayer connecting portion 20c is connected to the other end. For example, when a current flows from the terminal 301 to the semiconductor package 30a, as indicated by the broken lines L3 in FIG. 9, the current flows through the wiring portion 201A in the direction from the interlayer connecting portion 20c provided to the other end 2020 of the wiring portion 201A toward the terminal connecting portion 311, in the direction opposite to the current flowing through the terminal 301. Therefore, similarly to the example according to the first embodiment, it is possible to achieve stress alleviation in the terminal connecting portion 311, as well as inductance reduction.

Furthermore, because the semiconductor packages 30a, 30b are mounted on the wiring substrate 20 in a manner inserted into the through holes 210, the gap dimension between the terminals 301 to 303 and the wiring portions facing each other can be further reduced. As a result, inductance reduction can be further improved.

In the example illustrated in FIG. 8, the plurality of semiconductor packages 30a, 30b are arranged in such a manner that the package positions are aligned along an arrangement direction in the direction orthogonal (up-down direction in the drawing) to the terminal-protruding direction. Therefore, regarding the plurality of semiconductor packages 30a, the plurality of terminals 301, 302 are aligned along a line in the up-down direction on the right side of the packages, and the plurality of terminals 303 are aligned along a line in the up-down direction on the left side of the packages. The same applies to the plurality of semiconductor packages 30b. In this manner, by aligning the terminals in the up-down direction (direction orthogonal to the terminal-protruding direction) in the drawing, the effect of inductance reduction can be further improved. Furthermore, the structure of the cooling element 40 (structure of cooling surface) that cools the semiconductor packages 30a, 30b and the wiring substrate 20 is simplified.

According to the embodiments and modifications of the present invention described above, the following actions and effects can be achieved.

(1) As illustrated in FIGS. 3, 4, and the like, a power converter includes: a semiconductor package 30 in which a semiconductor element is incorporated and that has a connection terminal 301 to 303 protruding outward, and a wiring substrate 20 on which the semiconductor package 30 is mounted. The terminal 301 to 303 includes a bent portion 310 bent on a plane that is in parallel with the wiring substrate 20, and a terminal connecting portion 311 that is provided further on a tip-end side than the bent portion 310. The wiring substrate 20 includes a first wiring portion 201 to 203 that is provided on the substrate surface and to which the terminal 301 to 303 is bonded, and another second wiring portion (a positive electrode wiring 103p, a negative electrode wiring 103n, a U-phase output wiring 104U, a V-phase output wiring 104V, a W-phase output wiring 104W). The first wiring portion 201 to 203 extends from one end 201a, 202a, 203a that is a connecting section where the terminal 301 to 303 is connected, toward the semiconductor package 30, in a manner facing and extending along the terminal 301 to 303, and has the other end 201b, 202b, 203b connected to the second wiring portion, the other end being on the extending side.

In other words, the first wiring portion 201 to 203 has one end 201a, 202a, 203a connected to the terminal connecting portion 311, has the other ends 201b, 202b, and 203b connected to the second wiring portion, and faces the terminal 301 to 303 in such a manner that the direction from the other end 201b, 202b, and 203b to the one end 201a, 202a, and 203a extends along the terminal-protruding direction. As a result, the current passing through the wiring portion 201 to 203 is in the opposite direction of the current passing through the terminal 301 to 303, so that it is possible to achieve stress alleviation in the terminal connecting portion 311, as well as inductance reduction.

In the example of the configuration illustrated in FIGS. 8 and 9, the first wiring portion 201, 202A, 202B, 204A extends from the connecting section to which the terminal connecting portion 311 is connected, toward the semiconductor package 30a, 30b in a manner facing and extending along the terminal 301 to 303, and has an end, on the extending side, connected to the interlayer connecting portion 20c that is the second wiring portion (corresponding to the other end 201b, 202b, 203b, in the example illustrated in FIGS. 3 and 4). Also in this example, the current passing through the terminal 301 to 303 is in the opposite direction of the current passing through the wiring portions facing thereto, so that it is possible to achieve stress alleviation as well as inductance reduction in the terminal connecting portion 311.

(2) In (1) described above, as illustrated in FIG. 6 and the like, the wiring substrate 20 has a through hole 210, and the semiconductor package 30 is mounted on the wiring substrate 20 in a manner inserted into the through hole 210. Therefore, the gap dimension G between the terminal 301 to 303 and the wiring portion 201 to 203 can be further reduced, and the inductance-reducing effect can be further improved.

(3) Furthermore, when the semiconductor package 30 has the heat-dissipating surfaces 320, 321 on both of the front and rear surfaces, by providing cooling elements 40 on the heat-dissipating surfaces 320, 321 exposed from the front and rear surfaces of the substrate, through the through hole 210, the cooling performance for the semiconductor package 30 can be improved.

(4) In (2) described above, as illustrated in FIG. 3 and the like, the semiconductor package 30 includes a plurality of the terminals 301, 302 protruding from the same side surface, and the bent portions 310 provided to the pair of respective adjacent terminals 301, 302 are bent in directions approaching each other. By bending the bent portions 310 in directions approaching each other, in the manner described above, the inductance can be further reduced.

(5) In (1) described above, as illustrated in FIG. 8 and the like, a plurality of the semiconductor packages 30a, 30b are arranged on the wiring substrate 20 along a direction orthogonal to a direction in which the terminals 301 to 303 protrude, and the plurality of the semiconductor packages 30a, 30b are aligned along a direction of arrangement. Therefore, because the terminals are aligned in the direction orthogonal to the terminal-protruding direction, the inductance-reducing effect can be further improved. Furthermore, the cooling surface structure of the cooling element 40 that cools the semiconductor packages 30a, 30b and the wiring substrate 20 is simplified.

(6) In (1) described above, as illustrated in FIGS. 8, 9, and the like, the wiring substrate 20 is a multilayer substrate in which a plurality of wiring layers 20a1 to 20a4 are laminated in a substrate thickness direction, with an insulating layer 20b interposed therebetween, and the first wiring portion 201, 201A, 202A, 202B, 203A, 204A is disposed on a wiring layer 20al provided on the front surface side of the wiring substrate 20, and has the extending-side end (e.g., the other end 202b) connected to at least one of other wiring layers provided in the substrate thickness direction, by the interlayer connecting portion 20c. With such a configuration, the current flowing through the terminal is in the direction opposite to the direction of the current flowing through the first wiring portion, SO that it is possible to achieve stress alleviation in the terminal connecting portion 311, as well as inductance reduction.

(7) In (6) described above, as illustrated in FIG. 9 and the like, the wiring substrate 20 includes a wiring layer 20a4 on the side of the substrate rear surface, and the other wiring layer connected by the interlayer connecting portion 20c includes a wiring layer 20a4 on the side of the substrate rear surface, and a cooling element 40 that cools the wiring layer 20a4 that is on the side of the substrate rear surface is further provided. With such a configuration, it is possible to suppress a rise in temperature of the wiring substrate 20, to suppress deformation of members due to a temperature rise, and to alleviate the stress in the solder-bonded portion.

Each of the embodiments and modifications described above is merely examples, and the present invention is not limited to such examples, as long as the features of the invention are not impaired. Furthermore, although various embodiments and modifications have been described above, the present invention is not limited thereto. Other aspects conceivable within the scope of the technical idea of the present invention still fall within the scope of the present invention.

### REFERENCE SIGNS LIST

1 power converter
2 DC voltage source
3 motor
10 inverter circuit
11 gate driver circuit
12 control circuit
20 wiring substrate
20a1 to 20a4 conductor layer (wiring layer)
20b insulating layer
20c interlayer connecting portion
30, 30a, 30b semiconductor package
40 cooling element
100a, 100b semiconductor element
101, 102 capacitor
103p positive electrode wiring
103n negative electrode wiring
104U U-phase output wiring
104V V-phase output wiring
104W W-phase output wiring
201 to 204, 201A to 204A, 202B, 200p, 200n wiring portion
201a, 202a, 203a one end
201b, 202b, 203b other end
210 through hole
301, 302, 303 terminal
310 bent portion
311 terminal connecting portion
320, 321 heat-dissipating surface

1. A power converter comprising:
a semiconductor package in which a semiconductor element is incorporated, and that has a terminal for connecting, the terminal protruding outward; and
a wiring substrate on which the semiconductor package is mounted, wherein the terminal includes: a bent portion that is bent on a plane that is in parallel with the wiring substrate; and
a terminal connecting portion that is provided further on a tip-end side with respect to the bent portion,
the wiring substrate includes: a first wiring portion that is provided on a substrate surface and to which the terminal is bonded; and another second wiring portion, and
the first wiring portion extends from a connecting section where the terminal is connected, toward the semiconductor package, in a manner facing and extending along the terminal, and has an end connected to the second wiring portion, the end being on an extending side.

2. The power converter according to claim 1, wherein
the wiring substrate has a through hole, and
the semiconductor package is mounted on the wiring substrate in a manner inserted into the through hole.

3. The power converter according to claim 2, wherein
the semiconductor package has a first heat-dissipating surface exposed from the through hole on a front surface side of the substrate, and a second heat-dissipating surface exposed from the through hole on a rear surface side of the substrate, and
the power converter further comprises a first cooling element that cools the first heat-dissipating surface, and a second cooling element that cools the second heat-dissipating surface.

4. The power converter according to claim 1, wherein
the semiconductor package includes a plurality of the terminals protruding from a same side surface, and
the bent portions provided to a pair of adjacent ones of the terminals are bent in directions approaching each other.

5. The power converter according to claim 1, wherein
a plurality of the semiconductor packages are arranged on the wiring substrate in a direction orthogonal to a direction in which the terminals protrude, and
the plurality of semiconductor packages are aligned along a direction of arrangement.

6. The power converter according to claim 1, wherein
the wiring substrate is a multilayer substrate in which a plurality of wiring layers are laminated in a substrate thickness direction, with an insulating layer disposed therebetween, and
the first wiring portion is disposed on the wiring layer provided on a front surface side of the wiring substrate, and has an extending-side end connected to at least one of another wiring layer provided in the substrate thickness direction, by an interlayer connecting portion.

7. The power converter according to claim 6, wherein
the wiring substrate includes the wiring layer on a rear surface side of the substrate,
the other wiring layer connected by the interlayer connecting portion includes a wiring layer on the rear surface side of the substrate, and the power converter further comprises a third cooling element configured to cool the wiring layer on the rear surface side of the substrate.
